(19) United States
(12) Patent Application Publication
(10) Pub. No.: US 2019/0334107 A1
(43) Pub. Date: Oct. 31, 2019

(54) QUANTUM DOT FILM AND APPLICATIONS THEREOF

(71) Applicant: SABIC GLOBAL TECHNOLOGIES B.V., Bergen op Zoom (NL)

(72) Inventors: Sunyoung LEE, Seoul (KR); Chunim LEE, Gyeonggi-do (KR); Mohamed Shaker MOHAMED, Gyeonggi-do (KR); Seongnam LEE, Seoul (KR); Jeongmin LIM, Gyeonggi-do (KR); Kahee SHIN, Seoul (KR); Jong Woo LEE, Seoul (KR); Soonyoung HYUN, Gyeonggi-do (KR)

(21) Appl. No.: 16/468,372

(22) PCT Filed: Dec. 12, 2017
(86) PCT No.: PCT/IB2017/057855

§ 371 Date: Jun. 11, 2019

Related U.S. Application Data
(60) Provisional application No. 62/433,408, filed on Dec. 13, 2016.

(51) Int. Cl. H01L 51/50; H01L 51/00; H01L 51/52; H01L 33/06

(52) U.S. Cl. CPC H01L 51/502; H01L 51/0007; B82Y 20/00; H01L 33/06; H01L 51/5256

(57) ABSTRACT

A film for light emitting devices, the film formed from a process including a quantum dot solution disposed between a first layer and a second layer, where at least one of the first layer and second layer is a protective layer, and where the protective layer is formed by mixing a barrier polymer with a scavenger.

### TECHNICAL FIELD

The disclosure generally relates to light emitting device and methods and more particularly to methods and structures utilizing a quantum dot film.

### BACKGROUND

Direct conversion of electricity into light using semiconductor-based light-emitting diodes (LEDs) is widely accepted one of the most promising approaches to more efficient lighting. LEDs demonstrate high brightness, long operational lifetime, and low energy consumption performance that far surpass that of conventional lighting systems such as incandescent and fluorescent light sources. The LED field is currently dominated by semiconductor quantum-well emitters (based, e.g., on indium-gallium-nitride (InGaN)/gallium nitride (GaN)) fabricated by epitaxial methods on crystalline substrates (e.g., sapphire). These structures are highly efficient, reliable, mature and bright, but structural defects at the substrate and semiconductor interface caused by lattice mismatch and heating during operation generally limits such devices to point light source with limited flexible compatibility.

OLEDs are easily amendable to low-temperature, large-area processing, including fabrication on flexible substrates. Synthetic organic chemistry provides essentially an unlimited number of degrees of freedom for tailoring molecular properties to achieve specific functionality, from selective charge transport to color-tunable light emission. The prospect of high-quality lighting sources based on inexpensive “plastic” materials has driven a tremendous amount of research in the area of OLEDs. which in turn has led to the realization of several OLED-based high-tech products such as flat screen televisions and mobile communication devices. Several industrial giants such as Samsung, LG, Sony, and Panasonic are working to develop large-area white-emitting OLEDs both for lighting and display. Despite advances in the OLED field, there are a few drawbacks of this technology that might prevent its widespread use in commercial products. One problem is poor cost-efficiency caused at least in part by the complexity of the necessary device architecture, which requires multiple thermal deposition steps during manufacture. Another problem is their limited stability, particularly for deep-red and blue phosphorescent OLEDs. While improving greatly in recent years, they still do not meet the standards employed in high-end devices.

Chemically synthesized nanocrystal quantum dots (QDs) have emerged as a promising class of emissive materials for low-cost yet efficient LEDs. These luminescent nanomaterials feature size-controlled tunable emission wavelengths and provide improvements in color purity, stability and durability over organic molecules. In addition, as with organic materials, colloidal QDs can be fabricated and processed via inexpensive solution-based techniques compatible with lightweight, flexible substrates. Moreover, similar to other semiconductor materials, colloidal QDs feature almost continuous above-band-edge absorption and a narrow emission spectrum at near-band-edge energies. Distinct from bulk semiconductors, however, the optical spectra of QDs depend directly on their size. Specifically, their emission color can be continuously tuned from the infrared (IR) to ultraviolet (UV) by varying QD size and/or composition. The wide range spectral tunability is combined with high photoluminescence (PL) quantum yields (QYs) that approach unity in well-passivated structures. These unique properties of QDs have been explored for use in various devices such as LEDs, lasers, solar cells, and photo detectors.

It is known that the quantum dots can degrade when they are exposed in air and moisture. In presence of light, oxygen and moisture molecules may cause photo-oxidation and photo-corrosion on the surface of the quantum dots. Once quantum dots react with oxygen and moisture, new defects may be created on the surface of quantum dots. Such defects may result in decreased light emitting of quantum dots.

In conventional quantum dot films, a quantum dot may be disposed between a first barrier film and a second barrier film, as illustrated in FIG. 1. Suitable barrier films include polymers (e.g., PET); oxides such as silicon oxides, metal oxides, metal nitrides, metal carbides, metal oxynitrides, and combinations thereof. The barrier layers are typically formed using techniques employed in the film metallizing art such as sputtering, evaporation, chemical vapor deposition, plasma deposition, atomic layer deposition, plating and the like. Second barrier film is typically laminated on a quantum dot layer and often includes an adhesion surface or layer. The thickness of each of the conventional barrier layer is configured to eliminate wrinkling in a roll-to-roll or laminate manufacturing processes, as may be required by conventional methods described above.

Improvements in quantum dot films and methods of making the same, are needed.

### SUMMARY

A film for light emitting devices is disclosed. According to one example, the film is formed from a process comprising disposing a quantum dot solution between a first layer and a second layer; wherein at least one of the first layer and the second layer is a protective layer including a barrier polymer and a scavenger, the scavenger absorbing at least one of oxygen and water to prevent the at least one of oxygen and water from reacting with the quantum dot solution; curing the quantum dot solution to form a film having a stacked construction with a quantum dot layer between the first layer and the second layer.

According to an example, an article comprising a first layer and a second layer; a quantum dot layer disposed between the first layer and the second layer; and wherein at least one of the first layer and the second layer is a protective layer, the protective layer comprising a barrier polymer and a scavenger, wherein the protective layer inhibits the permeation of at least oxygen and moisture into the quantum dot layer.

According to a further example, the first layer and the second layer are protective layers including the barrier polymer and the scavenger. According to still another example, the film includes a substrate and wherein the first layer is disposed on the substrate, the quantum dot layer is disposed on the first layer opposite the substrate, and the second layer is disposed on the quantum dot layer opposite the first layer.

According to another example, the film further comprises a diffuser layer applied to the protective layer, wherein the diffuser layer is on a surface of the protective layer opposite the quantum dot layer.

According to another example, the first layer is a barrier layer comprising an inorganic layer disposed between a substrate and an adhesion layer, wherein the quantum dot solution is disposed on the first layer, and the second layer is the protective layer and is applied to the quantum dot layer.

According to a further example, a film for light emitting devices, the film formed from a process comprising disposing a quantum dot solution between a first layer and a second layer, where at least one of the first layer and second layer is a protective layer; and wherein the protective layer is formed by mixing a barrier polymer with a scavenger.

In yet another example, a method comprises: disposing a quantum dot solution on a first layer; applying a second layer to the quantum dot solution; wherein at least one of the first layer and second layer are a protective layer formed by providing a barrier polymer with a scavenger, wherein the scavenger absorbs at least one of oxygen and water to inhibit the at least one of oxygen and water from reacting with the quantum dot solution; and curing the first layer, second layer and quantum dot solution to form a film comprising a stack of the first layer, the quantum dot layer, and the second layer.

### BRIEF DESCRIPTION OF THE DRAWINGS

The above-mentioned and other features and advantages of this disclosure, and the manner of attaining them, will become apparent and be better understood by reference to the following description of one aspect of the disclosure in conjunction with the accompanying drawings, wherein:

FIG. 1 is a schematic representation of a composite layered structure according to aspects of the prior art.

FIG. 2 is a schematic representation of a composite layered structure according to examples of the present disclosure.

FIG. 3 is a schematic representation of a composite layered structure according to examples of the present disclosure.

FIG. 4 is a schematic representation of a composite layered structure according to examples of the present disclosure.

FIG. 5 is a method flow diagram according to aspects of the present disclosure.

FIG. 6 is a method flow diagram according to further aspects of the present disclosure.

FIG. 7 is a method flow diagram according to yet further aspects of the present disclosure.

### DETAILED DESCRIPTION

The disclosure relates to quantum dot films and methods of forming quantum dot films having reduced manufacturing complexity and film thickness (e.g., less than 50 micrometers (microns, μm), less than 100 micron, or other endpoint thicknesses between 5 microns and 50 microns or between 5 and 100 microns), among other aspects. A protective layer may be disposed adjacent a quantum dot layer to protect the quantum dot layer from oxygen and moisture. As an example, a at least one of the barrier layers of a conventional multi-layer film may be replaced with the protective layer of the present disclosure. The protective layer may include one or more layers. In one example, the protective layer includes a barrier polymer and a scavenger. In a further example, the protective layer may include a functional layer such as a diffuser layer or a prism disposed thereon. As a further example, the protective layer may include an inorganic layer or a hybrid layer. In still another example, the film includes a quantum dot solution disposed between a first layer and a second layer, where at least one of the first and second layers is a protective layer comprising a barrier polymer and a scavenger. The scavenger in this example inhibits at least one of oxygen and moisture i.e. water from reacting with the quantum dot solution by absorbing the at least one of oxygen and moisture. According to one example, the first layer is a barrier film, and the quantum dot solution is disposed on the barrier film and cured to form a quantum dot layer on a barrier film. The second layer is the protective layer and is applied to the quantum dot layer opposite the first layer. According to another example, the barrier polymer and scavenger are applied to a substrate to form the first layer and the quantum dot solution is disposed on the first layer, and the second layer comprising the barrier polymer and the scavenger is applied on the quantum dot layer such that both the first layer and second layer are protective layers. Other configurations may be used as the protective layer, as described herein. While the present disclosure is not so limited, an appreciation of various aspects of the disclosure will be gained through a discussion of the examples provided below.

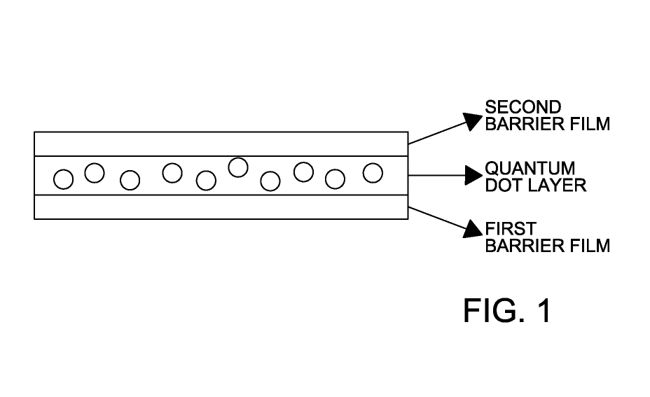

With reference to FIG. 1, a conventional quantum dot film includes a quantum dot solution disposed between first and second barrier films. The barrier films inhibit oxygen and moisture from reacting with the quantum dot layer by providing a physical barrier. However, these films are relatively thick and, thus, greatly contribute to the overall thickness of the quantum dot film by making up two thirds of the film thickness without additional functional layers. Also, they are relatively expensive to produce.

In accordance with the disclosure herein, at least one of the first and second barrier films in the conventional quantum dot film is replaced with a protective layer. The protective layer includes a barrier polymer provided with a scavenger, where the presence of the scavenger inhibits at least one of oxygen and moisture i.e. water from reaching the quantum dot solution as discussed more completely below. The protective layer of the disclosure is thinner than barrier layer reducing the overall thickness of quantum dot film, and may also reduce the cost of producing the quantum dot film.

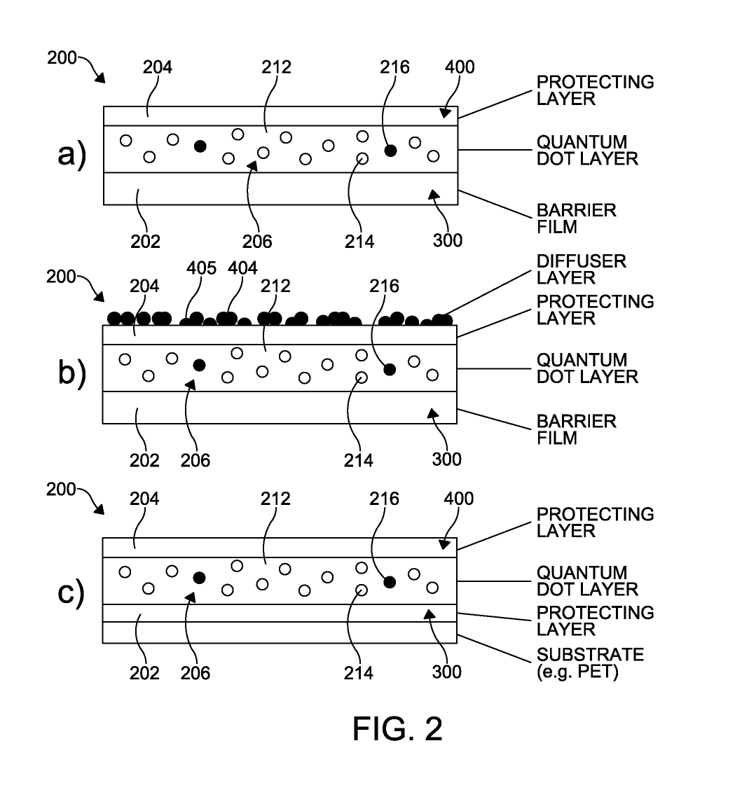

FIG. 2 is a schematic side elevation view of an illustrative quantum dot (QD) film 200. In one or more examples, the QD film 200 includes a first layer 202, a second layer 204, and a quantum dot layer 206 disposed between the first layer 202 and the second layer 204.

The quantum dot layer 206 may include a quantum dot solution 210 dispersed in a polymer material 212 such as acryl type, epoxy type, or silicone type polymers, or combinations thereof. The quantum dot layer 206 may include one or more populations of quantum dot material 214. Exemplary quantum dots or quantum dot material 214 emit green light and red light upon down-conversion of blue primary light from the blue LED to secondary light emitted by the quantum dots. The respective portions of red, green, and blue light can be controlled to achieve a desired white point for the white light emitted by a display device incorporating the quantum dot film article. Suitable quantum dots 214 for use in quantum dot film articles described herein include core/shell luminescent nanocrystals including cadmium selenium CdSe/zinc sulfide ZnS, indium phosphide InP/zinc sulfide ZnS, lead selenide PbSe/PbS, cadmium selenide CdSe/cadmium sulfide CdS, cadmium telluride CdTe/CdS or CdTe/ZnS. The quantum dot layer 206 can have any useful amount of quantum dots 214. In many aspects the quantum dot layer 206 can have from about 0.05 wt % to about 5 wt % quantum dots. It is understood that various intervening endpoints in the proposed size ranges may be used. However, other loadings of quantum dots 214 may be used.

The quantum dot layer 206 may include scattering beads or particles, schematically depicted at 216. The inclusion of scattering particles results in a longer optical path length and improved quantum dot absorption and efficiency. The particle size is in a range from 50 nanometers (nm) to 10 micrometers, or from 100 nm to 6 micrometers. It is understood that various intervening endpoints in the proposed size ranges may be used. The quantum dot layer 206 may include fillers such as fumed silica.

The first layer 202 may be formed of any useful material that can protect the quantum dots from environmental conditions such as oxygen and moisture. As discussed in more detail below, at least one of the first layer 202 and second layer 204 may be a protective layer 400.

In the example shown in FIG. 2, first layer 202 is a barrier film 300. Suitable barrier films include polymers, glass or dielectric materials, for example. Suitable barrier film materials include, but are not limited to, polymers such as polyethylene terephthalate (PET); oxides such as silicon oxide, titanium oxide, or aluminum oxide (e.g., SiO₂, Si₂O₃, TiO₂, or Al₂O₃); and suitable combinations thereof.

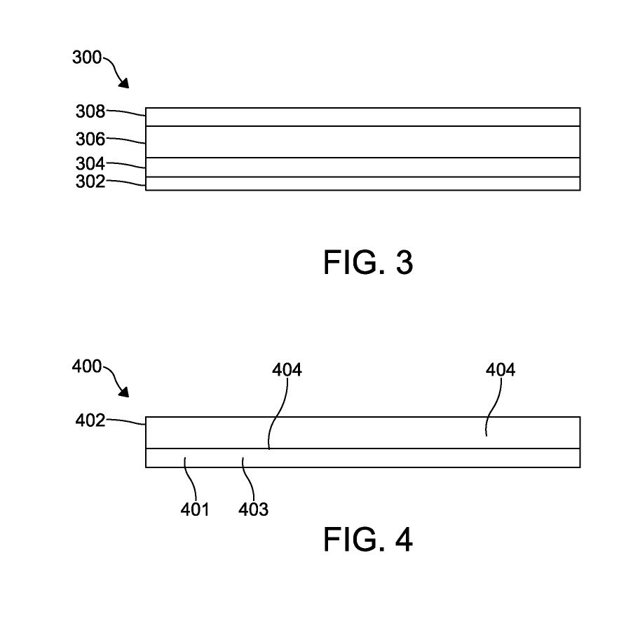

With reference to FIG. 3, the barrier layer 300 of the QD film 200 may include at least two layers of different materials or compositions, such that the multi-layered barrier eliminates or reduces pinhole defect alignment in the barrier layer, providing an effective barrier to oxygen and moisture penetration into the quantum dot layer 206. The QD film 200 may include any suitable material or combination of materials. In the examples shown in FIGS. 2(a) and 2(b), only one barrier layer is provided, however, additional barrier layers may be added outward of the structures shown in the figures if desired for a particular QD film application.

FIG. 3 illustrates an example barrier layer 300, which may be embodied as the first layer 202 (FIG. 2). As shown, the barrier layer 300 may include an inorganic layer 306 disposed on a base substrate 304 (e.g., polymer). Optionally, a diffuser layer 302 may be provided on substrate 304 opposite inorganic layer 306. The inorganic layer 306 may include inorganic material such as a polysilazane-based polymer, a polysiloxane-based polymer. The inorganic layer may include oxides such as silicon oxide, titanium oxide, or aluminum oxide (e.g., SiO₂, Si₂O₃, TiO₂, or Al₂O₃); and suitable combinations thereof. In certain aspects, a coating 308 may be applied, for example, adjacent the inorganic layer 306. The coating 308 may be an adhesive coating (e.g., organic layer) and may improve the adhesion property with a QD layer, for example.

FIG. 4 illustrates an example protective layer 400, which may be embodied as at least one of the first layer 202 and second layer 204. In the example shown in FIG. 2, second layer 204 is a protective layer 400. As shown in FIG. 4, the protective layer 400 may include a barrier polymer 401 combined with a scavenger 403. Barrier polymer 401 may be any polymer suitably used in a barrier film as described above. For example, barrier polymer 401 may include inorganic material used such as a polysilazane-based polymer, a polysiloxane-based polymer. As one non-limiting example, the conversion of the material may be performed according to the following reaction:

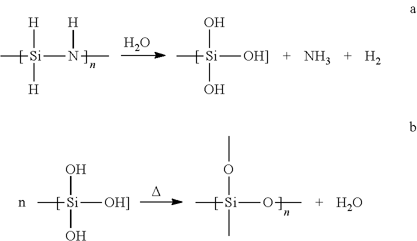

In addition, barrier polymer may include organic and inorganic hybrid materials. For example, the following structure may be used, where R1 is an organic component offering flexibility and R2 is an organic component that improves adhesion.

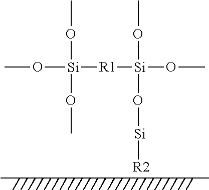

Scavenger 403 may be any compound that absorbs at least one of oxygen and moisture. For example, scavenger 403 may be a phenolic acid. Phenolic acids are types of aromatic acid compound. Included in that class are substances containing a phenolic ring and an organic carboxylic acid function (C6-C1 skeleton). Phenolic acids generally act as antioxidants by trapping free radicals. Phenolic acids will be used as scavenger 403 which reacts with oxygen and/or moisture in protecting layer 400. Phenolic acids can prevent permeation of at least one of oxygen and moisture from external atmosphere into quantum dot layer. There are several categories of phenolic acids including:

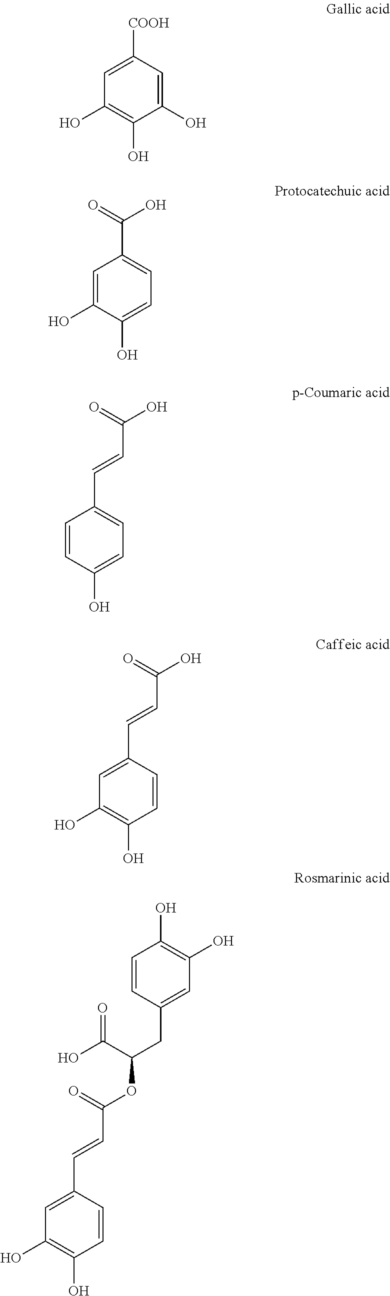 [SMILES: O=C(O)c1cc(O)c(O)c(O)c1 ; O=C(O)c1ccc(O)c(O)c1 ; O=C(O)/C=C/c1ccc(O)cc1 ; O=C(O)/C=C/c1ccc(O)c(O)c1 ; O=C(/C=C/c1ccc(O)c(O)c1)O[C@H](Cc1ccc(O)c(O)c1)C(=O)O]

According to one example, scavenger 403 included a protocatechuic acid. The reaction of protocatechuic acid with oxygen and moisture is representative of use of a phenolic acid as a scavenger according to the examples herein, as shown below:

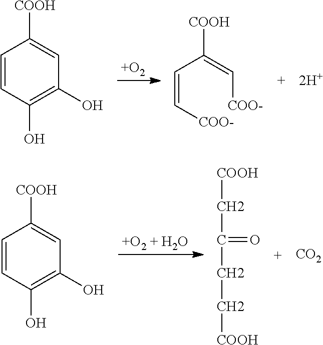

Optionally, protective layer 400 may include a functional layer 402. For example, functional layer 402 may be or include a diffuser layer 405 (FIG. 2(b)). Diffuser layer 405 may be applied on a side 404 of protective layer 400 opposite of quantum dot layer 206. In another example, functional layer 402 is a prism 407 (FIG. 4) to enhance brightness of the underlying film. Other functional or ornamental layers may be used such as a surface matt treatment and/or scratch resistant treatment as desired for a given application of film 200.

With reference to FIG. 2(b), according to another example, film 200 may include a functional layer 402 that is applied to one or more of the protective layers outward of quantum dot layer. Functional layer 402 may be applied to second layer 204 on a side of second layer opposite quantum dot layer. In this example, second layer 204 is a protective layer 400. Functional layer 402 may be a diffuser layer as schematically shown. Other functional or ornamental layers may be used such as surface matt treatment and/or scratch resistant treatment as desired for a given application of film 200

The protecting layer 400 may be formed by low temperature wet processes. As an example, the protective layer according to aspects of the present disclosure may be or comprise a flowable curable coating composition as described herein. As such, the flowable curable coating composition may be used to coat a surface such as a quantum dot layer 206 of a film 200. As an example, a low temperature wet process may include a coating method including but not limited to roll coating, gravure coating, knife coating, dip coating, curtain flow coating, spray coating, bar coating, die coating, spin coating, or inkjet coating and the like.

Once the protective layer is applied to the quantum dot layer 206, protective layer 400 may be separately cured according to curing methods appropriate for the material including but not limited to ultraviolet (UV) curing. As an illustrative example, ultraviolet (UV) curing may be performed in a gastight aluminum casing equipped with low pressure mercury lamps (Hg LP; Heraeus Noblelight NIQ 65XL). The lamps may be configured to emit in the UV domain at about 254 nm (20 watts, W) and in the vacuum ultraviolet (VUV) domain at about 185 nm (5 W) with a distance to the sample at 20 mm. A gas sweeping may be applied and may include a mixture of 99.9% pure dry nitrogen and 5% O₂ in dry nitrogen. Before beginning the curing of the sample, atmosphere may be purged with nitrogen during 10 min (8 liters per minute, L/min) and lamps may be allowed to heat to nominal power. The curing may occur with a partial pressure of oxygen at the surface of the sample inferior or equal to 1%.

With reference to FIG. 2C, a film 200 where both the first layer and second layer are protective layers is shown. In this example, first layer includes a substrate to which the protective solution is applied. Quantum dot solution may then be disposed on the first protective layer and cured. The second layer, which is also a protective layer, is then applied to quantum dot solution as discussed above. In the example shown, first protective layer is disposed on a substrate and cured to form first layer of film 200. A curable protective layer coating composition can be cured to provide a hardened film on the solid plastic form surface. The hardened film can provide an abrasion resistant coating layer. The hardened film can provide high surface hardness and a glass-like feel, and can provide a desirable combination of properties such as hardness, scratch resistance, mechanical strength, and impact resistance. A filler, polyester, or combination thereof, can produce a surprising increase in hardness as compared to the results of the treatment as performed on a solid plastic form free of filler and polyester.

The method can include coating a surface of a solid plastic form with a flowable curable coating composition. The coating can be performed in any suitable manner that forms a coating of the flowable curable coating composition on a surface of the solid plastic form. Wet or transfer coating methods can be used. For example, the coating can be bar coating, spin coating, spray coating, or dipping. Single- or multiple-side coating can be performed.

The solid plastic form can be transparent, opaque, or any one or more colors. The solid plastic form can include any one or more suitable plastics (e.g., as a homogeneous mixture of plastics). In some aspects, the solid plastic form can include at least one of an acrylonitrile butadiene styrene (ABS) polymer, an acrylic polymer, a celluloid polymer, a cellulose acetate polymer, a cycloolefin copolymer (COC), an ethylene-vinyl acetate (EVA) polymer, an ethylene vinyl alcohol (EVOH) polymer, a fluoroplastic, an ionomer, an acrylic/PVC alloy, a liquid crystal polymer (LCP), a polyacetal polymer (POM or acetal), a polyacrylate polymer, a polymethylmethacrylate polymer (PMMA), a polyacrylonitrile polymer (PAN or acrylonitrile), a polyamide polymer (PA or nylon), a polyamide-imide polymer (PAI), a polyaryletherketone polymer (PAEK), a polybutadiene polymer (PBD), a polybutylene polymer (PB), a polybutylene terephthalate polymer (PBT), a polycaprolactone polymer (PCL), a polychlorotrifluoroethylene polymer (PCTFE), a polytetrafluoroethylene polymer (PTFE), a polyethylene terephthalate polymer (PET), a polycyclohexylene dimethylene terephthalate polymer (PCT), a polycarbonate polymer (PC), a polyhydroxyalkanoate polymer (PHA), a polyketone polymer (PK), a polyester polymer, a polyethylene polymer (PE), a polyetheretherketone polymer (PEEK), a polyetherketoneketone polymer (PEKK), a polyetherketone polymer (PEK), a polyetherimide polymer (PEI), a polyethersulfone polymer (PES), a polyethylenechlorinate polymer (PEC), a polyimide polymer (PI), a polylactic acid polymer (PLA), a polymethylpentene polymer (PMP), a polyphenylene oxide polymer (PPO), a polyphenylene sulfide polymer (PPS), a polyphthalamide polymer (PPA), a polypropylene polymer, a polystyrene polymer (PS), a polysulfone polymer (PSU), a polytrimethylene terephthalate polymer (PTT), a polyurethane polymer (PU), a polyvinyl acetate polymer (PVA), a polyvinyl chloride polymer (PVC), a polyvinylidene chloride polymer (PVDC), a polyamideimide polymer (PAI), a polyarylate polymer, a polyoxymethylene polymer (POM), and a styrene-acrylonitrile polymer (SAN). In some aspects, the solid plastic form includes at least one of polycarbonate polymer (PC) and polymethylmethacrylate polymer (PMMA). The solid plastic form can include a blend of PC and PMMA.

The solid plastic form can include one type of polycarbonate or multiple types of polycarbonate. The polycarbonate can be made via interfacial polymerization (e.g., reaction of bisphenol with phosgene at an interface between an organic solution such as methylene chloride and a caustic aqueous solution) or melt polymerization (e.g., transesterification and/or polycondensation of monomers or oligomers above the melt temperature of the reaction mass). Although the reaction conditions for interfacial polymerization may vary, in an example the procedure can include dissolving or dispersing a dihydric phenol reactant in aqueous caustic soda or potash, adding the resulting mixture to a suitable water-immiscible solvent medium, and contacting the reactants with a carbonate precursor (e.g., phosgene) in the presence of a catalyst such as triethylamine or a phase transfer catalyst, under controlled pH conditions, e.g., about 8 to about 10. The most commonly used water-immiscible solvents include methylene chloride, 1,2-dichloroethane, chlorobenzene, toluene, and the like.

Alternatively, melt processes may be used to make the polycarbonates. Generally, in the melt polymerization process, polycarbonates may be prepared by co-reacting, in a molten state, the dihydroxy reactant(s) and a diaryl carbonate ester, such as diphenyl carbonate, in the presence of a transesterification catalyst in a mixer, twin screw extruder, or the like, to form a uniform dispersion. Volatile monohydric phenol can be removed from the molten reactants by distillation and the polymer can be isolated as a molten residue. In some aspects, a melt process for making polycarbonates uses a diaryl carbonate ester having electron-withdrawing substituents on the aryl groups, such as bis(4-nitrophenyl)carbonate, bis(2-chlorophenyl)carbonate, bis(4-chlorophenyl)carbonate, bis(methyl salicyl)carbonate, bis(4-methylcarboxylphenyl)carbonate, bis(2-acetylphenyl)carboxylate, bis(4-acetylphenyl)carboxylate, or a combination thereof. In addition, transesterification catalysts for use may include phase transfer catalysts such as tetrabutylammonium hydroxide, methyltributylammonium hydroxide, tetrabutylammonium acetate, tetrabutylphosphonium hydroxide, tetrabutylphosphonium acetate, tetrabutylphosphonium phenolate, or a combination thereof.

The one or more polycarbonates can be about 50 wt % to about 100 wt % of the solid plastic form, such as about 50 wt % or less, or about 55 wt %, 60, 65, 70, 75, 80, 85, 90, 95, 96, 97, 98, 99, 99.9 wt %, or about 99.99 wt % or more. In various aspects, the polycarbonate can include a repeating group having the structure:

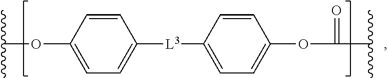

Each phenyl ring in the structure is independently substituted or unsubstituted. The variable L³ is chosen from —S(O)₂— and substituted or unsubstituted (C₁-C₂₀)hydrocarbylene. In various aspects, the polycarbonate can be derived from bisphenol A, such that the polycarbonate includes a repeating group having the structure:

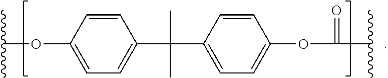

The solid plastic form can include a filler, such as one filler or multiple fillers. The filler can be any suitable type of filler. The filler can be homogeneously distributed in the solid plastic form. The one or more fillers can form about 0.001 wt % to about 50 wt % of the solid plastic form, or about 0.01 wt % to about 30 wt %, or about 0.001 wt % or less, or about 0.01 wt %, 0.1, 1, 2, 3, 4, 5, 10, 15, 20, 25, 30, 35, 40, 45 wt %, or about 50 wt % or more. The filler can be fibrous or particulate. The filler can be aluminum silicate (mullite), synthetic calcium silicate, zirconium silicate, fused silica, crystalline silica graphite, natural silica sand, or the like; boron powders; oxides such as TiO₂, aluminum oxide, magnesium oxide, or the like; calcium sulfate (as its anhydride, dehydrate or trihydrate); calcium carbonates such as chalk, limestone, marble, synthetic precipitated calcium carbonates, or the like; talc, including fibrous, modular, needle shaped, lamellar talc, or the like; wollastonite; surface-treated wollastonite; glass spheres such as hollow and solid glass spheres; kaolin; single crystal fibers or “whiskers” such as silicon carbide, alumina, boron carbide, iron, nickel, copper, or the like; fibers (including continuous and chopped fibers) such as asbestos, carbon fibers, glass fibers; sulfides such as molybdenum sulfide, zinc sulfide, or the like; barium compounds; metals and metal oxides such as particulate or fibrous materials; flaked fillers; fibrous fillers, for example short inorganic fibers such as those derived from blends including at least one of aluminum silicates, aluminum oxides, magnesium oxides, and calcium sulfate hemihydrate or the like; natural fillers and reinforcements; organic fillers such as polytetrafluoroethylene, reinforcing organic fibrous fillers formed from organic polymers capable of forming fibers such as poly(ether ketone), polyimide, polybenzoxazole, poly(phenylene sulfide), polyesters, polyethylene, aromatic polyamides, aromatic polyimides, polyetherimides, polytetrafluoroethylene, acrylic resins, poly(vinyl alcohol) or the like; or combinations including at least one of the foregoing fillers. The filler can be selected from glass fibers, carbon fibers, a mineral fillers, or combinations thereof. The filler can be glass fibers.

The glass fibers can be selected from E-glass, S-glass, AR-glass, T-glass, D-glass, R-glass, and combinations thereof. The glass fibers used can be selected from E-glass, S-glass, and combinations thereof. High-strength glass is generally known as S-type glass in the United States, R-glass in Europe, and T-glass in Japan. High-strength glass has appreciably higher amounts of silica oxide, aluminum oxide and magnesium oxide than E-glass. S-2 glass is approximately 40-70% stronger than E-glass. The glass fibers can be made by standard processes, e.g., by steam or air blowing, flame blowing, and mechanical pulling.

The glass fibers can be sized or unsized. Sized glass fibers are coated on their surfaces with a sizing composition selected for compatibility with the polycarbonate. The sizing composition facilitates wet-out and wet-through of the polycarbonate on the fiber strands and assists in attaining desired physical properties in the polycarbonate composition. The glass fibers can be sized with a coating agent. The coating agent can be present in an amount from about 0.1 wt % to about 5 wt %, or about 0.1 wt % to about 2 wt %, based on the weight of the glass fibers.

In preparing the glass fibers, a number of filaments can be formed simultaneously, sized with the coating agent and then bundled into what is called a strand. Alternatively the strand itself may be first formed of filaments and then sized. The amount of sizing employed is generally that amount which is sufficient to bind the glass filaments into a continuous strand and can be about 0.1 to about 5 wt %, about 0.1 to 2 wt %, or about 1 wt %, based on the weight of the glass fibers.

The glass fibers can be continuous or chopped. Glass fibers in the form of chopped strands may have a length of about 0.3 millimeters (mm) to about 10 centimeters (cm), about 0.5 cm to about 5 cm, or about 1.0 mm to about 2.5 cm. In various further aspects, the glass fibers can have a length of about 0.2 mm to about 20 mm, about 0.2 mm to about 10 mm, or about 0.7 mm to about 7 mm, 1 mm or longer, or 2 mm or longer. The glass fibers can have a round (or circular), flat, or irregular cross-section. The diameter of the glass fibers can be about 1 μm to about 15 μm, about 4 to about 10 μm, about 1 μm to about 10 μm, or about 7 μm to about 10 μm.

The solid plastic form can include a polyester. The polyester can be any suitable polyester. The polyester can be chosen from aromatic polyesters, poly(alkylene esters) including poly(alkylene arylates) (e.g., poly(alkylene terephthalates)), and poly(cycloalkylene diesters) (e.g., poly(cyclohexanedimethylene terephthalate) (PCT), or poly(1,4-cyclohexane-dimethanol-1,4-cyclohexanedicarboxylate) (PCCD)), and resorcinol-based aryl polyesters. The polyester can be poly(isophthalate-terephthalate-resorcinol)esters, poly(isophthalate-terephthalate-bisphenol A)esters, poly[(isophthalate-terephthalate-resorcinol)ester-co-(isophthalate-terephthalate-bisphenol A)]ester, or a combination including at least one of these. Examples of poly(alkylene terephthalates) include poly(ethylene terephthalate) (PET), poly(1,4-butylene terephthalate) (PBT), and poly(propylene terephthalate) (PPT). Also useful are poly(alkylene naphthoates), such as poly(ethylene naphthanoate) (PEN), and poly(butylene naphthanoate) (PBN). Copolymers including alkylene terephthalate repeating ester units with other ester groups can also be useful. Useful ester units can include different alkylene terephthalate units, which can be present in the polymer chain as individual units, or as blocks of poly(alkylene terephthalates). Specific examples of such copolymers include poly(cyclohexanedimethylene terephthalate)-co-poly(ethylene terephthalate), abbreviated as PETG where the polymer includes greater than or equal to 50 mol % of poly(ethylene terephthalate), and abbreviated as PCTG where the polymer includes greater than 50 mol % of poly(1,4-cyclohexanedimethylene terephthalate). The polyester can be substantially homogeneously distributed in the solid plastic form. The solid plastic form can include one type of polyester or multiple types of polyester. The one or more polyesters can form any suitable proportion of the solid plastic form, such as about 0.001 wt % to about 50 wt % of the solid plastic form, about 0.01 wt % to about 30 wt %, or about 0.001 wt % or less, or about 0.01 wt %, 0.1, 1, 2, 3, 4, 5, 6, 8, 10, 12, 14, 16, 18, 20, 22, 24, 26, 28, 30, 35, 40, 45 wt %, or about 50 wt % or more. The polyester can includes a repeating unit having the structure:

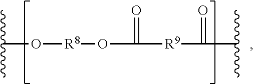

The variables R⁸ and R⁹ can be independently substituted or unsubstituted (C₁-C₂₀)hydrocarbylene. The variables R⁸ and R⁹ can be cycloalkylene-containing groups or aryl-containing groups. The variables R⁸ and R⁹ can be independently substituted or unsubstituted phenyl, or substituted or unsubstituted —(C₀-C₁₀)hydrocarbyl-(C₄-C₁₀)cycloalkyl-(C₀-C₁₀)hydrocarbyl-. The variables R⁸ and R⁹ can both be cycloalkylene-containing groups. The variables R⁸ and R⁹ can independently have the structure:

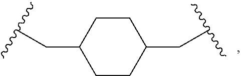 [SMILES: *CC1CCC(C*)CC1]

wherein the cyclohexylene can be substituted in a cis or trans fashion. In some examples, R9 can be a para-substituted phenyl, such that R⁹ appears in the polyester structure as:

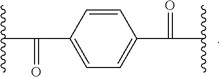 [SMILES: *C(=O)c1ccc(C(*)=O)cc1]

The solid plastic form can have any suitable shape and size. In some aspects, the solid plastic form is a sheet having any suitable thickness, such as a thickness of about 25 microns to about 50,000 microns, about 25 microns to about 15,000 microns, about 60 microns to about 800 microns, or about 25 microns or less, or about 50, 75, 100, 150, 200, 250, 300, 400, 500, 600, 700, 800, 900, 1,000, 1,500, 2,000, 3,000, 4,000, 5,000, 6,000, 8,000, 10,000, 12,000, 14,000, 15,000, 20,000, 25,000, 30,000, 40,000, or about 50,000 microns or more.

The flowable curable coating composition can include a) an alicyclic epoxy group-containing siloxane resin having a weight average molecular weight of about 1,000 to about 4,000 and a (M_{w}/Mₙ) of about 1.05 to about 1.4, b) an epoxy-functional organosiloxane and an organosiloxane comprising a isocyanate group or an isocyanurate group, or both a) and b).

The epoxy-functional oganosiloxane can have the structure:

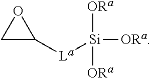

At each occurrence, R^{a} can be independently substituted or unsubstituted (C₁-C₁₀)alkyl. At each occurrence, the variable R can be independently unsubstituted (C₁-C₆)alkyl. The variable La can be substituted or unsubstituted (C₁-C₃₀)hydrocarbyl interrupted by 0, 1, 2, or 3 groups independently chosen from —O—, —S—, substituted or unsubstituted —NH—, —(Si(OR^{a})₂)ₙ₁—, —(O—CH₂—CH₂)ₙ₁—, and —(O—CH₂—CH₂—CH₂)ₙ₁—, wherein n can be about 1 to about 1,000 (e.g., 1-100, 1-50, 1-10, 1, 2, 3, 4, 5, 6, 8, 10, 12, 14, 16, 18, 20, 25, 30, 40, 50, 75, 100, 200, 250, 500, 750, 1,000). The variable La can be an unsubstituted (C₁-C₃₀)hydrocarbyl interrupted by 0, 1, 2, or 3 groups independently chosen from —O— and —S—. The epoxy-functional organosiloxane can be 2-(3,4-epoxycyclohexyl)ethyltrimethoxysilane, 3-glycidoxypropyl methyldimethoxysilane, 3-glycidoxypropyl trimethoxysilane, 3-glycidoxypropyl methyldiethoxysilane, or 3-glycidoxypropyl triethoxysilane. The flowable curable resin composition can include one epoxy-functional organosiloxane, or multiple epoxy-functional organosiloxanes. The one or more epoxy-functional organosiloxanes can be any suitable proportion of the flowable curable resin composition such as about 0.01 wt % to about 100 wt %, 10 wt % to about 100 wt %, about 50 wt % to about 99.9 wt %, or about 0.01 wt % or less, or about 0.1 wt %, 1, 2, 3, 4, 5, 6, 8, 10, 12, 14, 15, 20, 25, 30, 35, 40, 45, 50, 55, 60, 65, 70, 75, 80, 85, 90, 95, 96, 97, 98, 99, 99.9, or about 99.99 wt %.

The organosiloxane including an isocyanate group can have the structure (R^{b})₄₋ₚSi(R^{c})ₚ. The variable p can be 1 to 4 (e.g., 1, 2, 3, or 4). At each occurrence, R^{b} can be independently chosen from substituted or unsubstituted (C₁-C₁₀)alkyl and substituted or unsubstituted (C₁-C₁₀)alkoxy. At each occurrence, R^{b} can be independently chosen from unsubstituted (C₁-C₆)alkyl and unsubstituted (C₁-C₆)alkoxy. At each occurrence, R^{c} can be -L^{b}-NCO, wherein L^{b} can be a substituted or unsubstituted (C₁-C₃₀)hydrocarbyl interrupted by 0, 1, 2, or 3 groups independently chosen from —O—, —S—, substituted or unsubstituted —NH—, —(Si(OR^{b})₂)ₙ₂—, —(O—CH₂—CH₂)ₙ₂—, and —(O—CH₂—CH₂—CH₂)ₙ₂—, wherein n2 can be about 1 to about 1,000 (e.g., 1-100, 1-50, 1-10, 1, 2, 3, 4, 5, 6, 8, 10, 12, 14, 16, 18, 20, 25, 30, 40, 50, 75, 100, 200, 250, 500, 750, 1,000). At each occurrence, LE can be an unsubstituted (C₁-C₃₀)hydrocarbyl interrupted by 0, 1, 2, or 3 groups independently chosen from —O— and —S—. The organosiloxane including the isocyanate group can be 3-isocyanatepropyltriethoxysilane. The flowable curable resin composition can include one or more than one organosiloxane including an isocyanate group. The one or more organosiloxanes including an isocyanate group can form any suitable proportion of the flowable curable resin composition, such as about 0.01 wt % to about 100 wt %, 10 wt % to about 100 wt %, about 50 wt % to about 99.9 wt %, or about 0.01 wt % or less, or about 0.1 wt %, 1, 2, 3, 4, 5, 6, 8, 10, 12, 14, 15, 20, 25, 30, 35, 40, 45, 50, 55, 60, 65, 70, 75, 80, 85, 90, 95, 96, 97, 98, 99, 99.9, or about 99.99 wt %.

The organosiloxane including an isocyanurate group can have the structure:

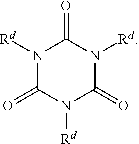

At each occurrence, R^{d} can be chosen from —H and -L^{c}-Si(R^{e})₃, wherein at least one R^{d} is -L^{c}-Si(R^{e})₃. At each occurrence, R^{d} can be -L^{c}-Si(R^{e})₃. At each occurrence, LE can be independently a substituted or unsubstituted (C₁-C₃₀)hydrocarbyl interrupted by 0, 1, 2, or 3 groups independently chosen from —O—, —S—, substituted or unsubstituted —NH—, —(Si(R^{e})₂)ₙ₃—, —(O—CH₂—CH₂)ₙ₃—, and —(O—CH₂—CH₂—CH₂)ₙ₃—, wherein n3 can be about 1 to about 1,000 (e.g., 1-100, 1-50, 1-10, 1, 2, 3, 4, 5, 6, 8, 10, 12, 14, 16, 18, 20, 25, 30, 40, 50, 75, 100, 200, 250, 500, 750, 1,000). At each occurrence, LE can be an unsubstituted (C₁-C₃₀)hydrocarbyl interrupted by 0, 1, 2, or 3 groups independently chosen from —O— and —S—. At each occurrence, R can be chosen from substituted or unsubstituted (C₁-C₁₀)alkyl and substituted or unsubstituted (C₁-C₁₀)alkoxy. At each occurrence, R can be independently chosen from unsubstituted (C₁-C₆)alkyl and unsubstituted (C₁-C₆)alkoxy. The organosiloxane including the isocyanate group or isocyanurate group can be tris-[3-(trimethoxysilyl propyl)-isocyanurate. The flowable curable resin composition can include one or multiple organosiloxanes including an isocyanurate group. Any suitable proportion of the flowable curable resin composition can be the one or more organosiloxanes including an isocyanurate group, such as about 0.01 wt % to about 100 wt %, 10 wt % to about 100 wt %, about 50 wt % to about 99.9 wt %, or about 0.01 wt % or less, or about 0.1 wt %, 1, 2, 3, 4, 5, 6, 8, 10, 12, 14, 15, 20, 25, 30, 35, 40, 45, 50, 55, 60, 65, 70, 75, 80, 85, 90, 95, 96, 97, 98, 99, 99.9, or about 99.99 wt %.

The flowable curable resin composition can include a bis(organosiloxane)-functional amine. In some aspects, the flowable curable resin composition includes an epoxy-functional organosiloxane, an organosiloxane comprising a isocyanate group or an isocyanurate group, and a bis(organosiloxane)-functional amine. The bis(organosiloxane)-functional amine can have the structure R^{f}₃Si-L^{d}-NH-L^{d}-SiR^{f}₃. At each occurrence, R^{f} can be chosen from substituted or unsubstituted (C₁-C₁₀)alkyl and substituted or unsubstituted (C₁-C₁₀)alkoxy. At each occurrence, R^{f} can be independently chosen from unsubstituted (C₁-C₆)alkyl and unsubstituted (C₁-C₆)alkoxy. At each occurrence, L^{d} can be independently a substituted or unsubstituted (C₁-C₃₀)hydrocarbyl interrupted by 0, 1, 2, or 3 groups independently chosen from —O—, —S—, substituted or unsubstituted —NH—, —(Si(R^{f})₂)ₙ₄—, —(O—CH₂—CH₂)ₙ₄—, and —(O—CH₂—CH₂—CH₂)ₙ₄—, wherein n4 can be about 1 to about 1,000 (e.g., 1-100, 1-50, 1-10, 1, 2, 3, 4, 5, 6, 8, 10, 12, 14, 16, 18, 20, 25, 30, 40, 50, 75, 100, 200, 250, 500, 750, 1,000). At each occurrence, L^{d} can be an unsubstituted (C₁-C₃₀)hydrocarbyl interrupted by 0, 1, 2, or 3 groups independently chosen from —O— and —S—. The bis(organosiloxane)-functional amine can be bis(triethoxysilylpropyl)amine, bis(trimethoxysilylpropyl)amine, or bis(methyldiethoxysilylpropyl) amine. The flowable curable resin composition can include one or more bis(organosiloxane)-functional amines. The one or more bis(organosiloxane)-functional amines can form any suitable proportion of the flowable curable resin composition, such as about 0.01 wt % to about 100 wt %, 10 wt % to about 100 wt %, about 50 wt % to about 99.9 wt %, or about 0.01 wt % or less, or about 0.1 wt %, 1, 2, 3, 4, 5, 6, 8, 10, 12, 14, 15, 20, 25, 30, 35, 40, 45, 50, 55, 60, 65, 70, 75, 80, 85, 90, 95, 96, 97, 98, 99, 99.9, or about 99.99 wt %.

The method can include performing a hydrolysis and condensation reaction using water and a catalyst to form a sol (e.g., colloidal suspension), releasing alcohol or water. The sol can include the flowable curable resin composition. Coating the surface of the solid plastic form can include coating the solid plastic form with the sol. Curing the curable coating composition can include curing the sol on the plastic form, to provide the hardened film (e.g., gel) on the solid plastic form surface.

The flowable curable coating composition can include an alicyclic epoxy group-containing siloxane resin. The flowable curable coating composition can include one type of alicyclic epoxy group-containing siloxane resin or multiple types of such resin. The one or more alicyclic epoxy group-containing siloxane resin can form any suitable proportion of the flowable curable coating composition, such as about 0.01 wt % to about 100 wt %, 10 wt % to about 100 wt %, about 50 wt % to about 99.9 wt %, or about 0.01 wt % or less, or about 0.1 wt %, 1, 2, 3, 4, 5, 6, 8, 10, 12, 14, 15, 20, 25, 30, 35, 40, 45, 50, 55, 60, 65, 70, 75, 80, 85, 90, 95, 96, 97, 98, 99, 99.9, or about 99.99 wt %. The siloxane resin can have a weight average molecular weight of about 1,000 to about 4,000 (e.g., about 1,000, 1,200, 1,400, 1,600, 1,800, 2,000, 2,200, 2,400, 2,600, 2,800, 3,000, 3,200, 3,400, 3,600, 3,800, or 4,000) and a (M_{w}/Mₙ) (i.e., weight average molecular weight divided by number average molecular weight, also referred to as polydispersity, a measure of the heterogeneity of sizes of molecules in the mixture) of about 1.05 to about 1.4 (e.g., about 1.05, 1.2, 1.4, 1.6, 1.8, 2.0, 2.2, 2.4, 2.6, 2.8, 3.0, 3.2, 3.4, 3.6, 3.8, or about 4.0 or more).

The siloxane resin can be prepared by hydrolysis and condensation, in the presence of water and an optional catalyst, of (i) an alkoxysilane including an alicyclic epoxy group and an alkoxy group having the structure R¹ₙSi(OR²)₄₋ₙ alone, wherein R¹ is (C₃-C₆)cycloalkyl(C₁-C₆)alkyl wherein the cycloalkyl group includes an epoxy group, R² is (C1-C7)alkyl, and n is 1-3, or (ii) the alkoxysilane having the structure R¹ₙSi(OR²)₄₋ₙ and an alkoxysilane having the structure R³ₘSi(OR⁴)₄₋ₘ, wherein R³ is chosen from (C₁-C₂₀)alkyl, (C₃-C₈)cycloalkyl, (C₂-C₂₀)alkenyl, (C₂-C₂₀)alkynyl, (C₆-C₂₀)aryl, an acryl group, a methacyl group, a halogen group, an amino group, a mercapto group, an ether group, an ester group, a carbonayl group, a carboxyl group, a vinyl group, a nitro group, a sulfone group, and an alkyd group, R⁴ is (C₁-C₇)alkyl, and m is 0 to 3. The alkoxysilxane having the structure R¹ₙSi(OR²)₄₋ₙ can be 2-(3,4-epoxycyclohexyl)ethyltrimethoxysilane or 2-(3,4-epoxycyclohexyl)ethyltriethoxysilane. The alkoxysilane having the structure R³ₘSi(OR⁴)₄₋ₘ can be one or more chosen from tetramethoxysilane, tetraethoxysilane, methyltrimethoxysilane, methyltriethoxysilane, methyltripropoxysilane, dimethyldimethoxysilane, dimethyldiethoxysilane, phenyltrimethoxysilane, phenyltriethoxysilane, diphenyldimethoxysilane, diphenyldiethoxysilane, triphenylmethoxysilane, triphenylethoxysilane, ethyltriethoxysilane, propylethyltrimethoxysilane, vinyltrimethoxysilane, vinyltriethoxysilane, vinyltripropoxysilane, N-(3-acryloxy-2-hydroxypropyl)-3-aminopropyltrimethoxysilane, N-(3-acryloxy-2-hydroxypropyl)-3-aminopropyltriethoxysilane, N-(3-acryloxy-2-hydroxypropyl)-3-aminopropyltripropoxysilane, 3-acryloxypropylmethylbis (trimethoxy) silane, 3-acryloxypropyltrimethoxysilane, 3-acryloxypropyltriethoxysilane, 3-acryloxypropyltripropoxysilane, 3-(meth)acryloxypropyltrimethoxysilane, 3-(meth)acryloxypropyltriethoxysilane, 3-(meth)acryloxypropyltripropoxysilane, N-(aminoethyl-3-aminopropyl)trimethoxysilane, N-(2-aminoethyl-3-aminopropyl)triethoxysilane, 3-aminopropyltrimethoxysilane, 3-aminopropyltriethoxysilane, chloropropyltrimethoxysilane, chloropropyltriethoxysilane, and heptadecafluorodecyltrimethoxysilane.

The flowable curable coating composition can further include a reactive monomer capable of reacting with the alicyclic epoxy group to form crosslinking. The flowable curable coating composition can include one such monomer or multiple such monomers. The one or more reactive monomers can form any suitable proportion of the flowable curable coating composition, such as about 0.001 wt % to about 30 wt %, or about 0.01 wt % to about 10 wt %, or about 0.001 wt % or less, or about 0.01 wt %, 0.1, 1, 2, 3, 4, 5, 6, 8, 10, 12, 14, 16, 18, 20, 22, 24, 26, 28, or about 30 wt % or more. The one or more reactive monomer can be present in any suitable weight ratio to the epoxy-containing siloxane resin, such as about 1:1000 to about 1:10, or about 1:1000 or less, or about 1:500, 1:250, 1:200, 1:150, 1:100, 1:80, 1:60, 1:40, 1:20, or about 1:10 or more. The reactive monomer can be an acid anhydride monomer, an oxetane monomer, or a monomer having an alicyclic epoxy group as a (C₃-C₆)cycloalkyl group. The acid anhydride monomer can be one or more chosen from phthalic anhydride, tetrahydrophthalic anhydride, hexahydrophthalic anhydride, nadic methyl anhydride, chlorendic anhydride, and pyromellitic anhydride. The oxetane monomer can be one or more chosen from 3-ethyl-3-hydroxymethyloxetane, 2-ethylhexyloxetane, xylene bis oxetane, and 3-ethyl-3[[3-ethyloxetan-3-yl]methoxy]oxetane. The reactive monomer having an alicyclic epoxy group can be one or more chosen from 4-vinylcycloghexene dioxide, cyclohexene vinyl monoxide, (3,4-epoxycyclohexyl)methyl 3,4-epoxycyclohexylcarboxylate, 3,4-epoxycyclohexylmethyl methacrylate, and bis(3,4-epoxycyclohexylmethyl)adipate.

In various aspects, one or more catalysts are present. In other aspects, the flowable curable coating composition can be free of catalyst. The catalyst can be any suitable catalyst, such as acidic catalysts, basic catalysts, ion exchange resins, and combinations thereof. For example, the catalyst can be hydrochloric acid, acetic acid, hydrogen fluoride, nitric acid, sulfuric acid, chlorosulfonic acid, iodic acid, pyrophosphoric acid, ammonia, potassium hydroxide, sodium hydroxide, barium hydroxide, imidazole, and combinations thereof.

The curable flowable coating composition can include one or more organic solvents, such as in an amount of about 0.01 to about 10 parts by weight, based on 100 parts by weight of the siloxane resin, or about 0.1 to about 10 parts by weight. The one or more solvents can be about 0.001 wt % to about 50 wt % of the curable flowable coating composition, about 0.01 wt % to about 30 wt %, about 30 wt % to about 70 wt/%, or about 0.001 wt % or less, or about 0.01 wt %, 0.1, 1, 2, 3, 4, 5, 6, 8, 10, 12, 14, 16, 18, 20, 22, 24, 26, 28, 30, 35, 40, 45 wt %, or about 50 wt % or more.

The flowable curable coating composition can further includes one or more polymerization initiators chosen from UV initiators, thermal initiators, onium salts, organometallic salts, amines, and imidazoles in an amount of about 0.01 to about 10 parts by weight, based on 100 parts by weight of the siloxane resin, or about 0.1 to about 10 parts by weight. The one or more polymerization initiators can be about 0.001 wt % to about 50 wt % of the curable flowable coating composition, about 0.01 wt % to about 30 wt %, or about 0.001 wt % or less, or about 0.01 wt %, 0.1, 1, 2, 3, 4, 5, 6, 8, 10, 12, 14, 16, 18, 20, 22, 24, 26, 28, 30, 35, 40, 45 wt %, or about 50 wt % or more.

The flowable curable coating composition can further include one or more additives, such as chosen from an antioxidant, a leveling agent, an antifogging agent, an antifouling agent, and a coating control agent. According to the disclosure, a scavenger is provided within the flowable curable coating composition when forming a protective layer. The scavenger inhibits at least one of oxygen and moisture from contacting the quantum dot layer and reacting with it.

The method can also include curing the curable coating composition, to provide a hardened film on the solid plastic form surface. The curing can be any suitable curing. The curing can be thermal curing. The curing can be UV curing. The curing can be a combination of thermal and UV curing (e.g., in parallel or sequential).

The hardened film on the solid plastic form can have any suitable thickness, such as about 1 micron to about 1,000 microns, about 1 micron to about 100 microns, about 5 microns to about 75 microns, or about 1 micron, 2, 3, 4, 5, 6, 8, 10, 12, 14, 16, 18, 20, 25, 30, 35, 40, 45, 50, 55, 60, 65, 70, 75, 80, 85, 90, 95, 100, 200, 500, 750, or about 1,000 microns or more.

The hardened film on the solid plastic form surface can have any suitable hardness. For example, the hardened film on the solid plastic form surface can have a hardness, namely a pencil hardness of about 3B to about 9H, or about HB to about 8H, or about 3B or less, or about 2B, B, HB, F, H, 2H, 3H, 4H, 5H, 6H, 7H, 8H, or about 9H or more. Pencil hardness is a measure of the hardness of a material on a scale ranging from 9H (hardest) to 9B (softest). In general, the pencil hardness scale is 9H (hardest), 8H, 7H, 6H, 5H, 4H, 3H, 2H, H, F, HB (medium), B, 2B, 3B, 4B, 5B, 6B, 7B, 8B, and 9B (softest), for example, at a 700 grams (g) or 1 kg load. In an aspect, the hardened film on the solid plastic form surface may have a pencil hardness of about 3B to about 9H, or about HB to about 8H, or about 3B or less, or about 2B, B, HB, F, H, 2H, 3H, 4H, 5H, 6H, 7H, 8H, or about 9H or more. Pencil hardness may be determined according to ASTM D3363 at a 1 kg load, for example.

### Methods of Making

In one or more aspects, and with reference to FIG. 2 for example, a method of forming a quantum dot film 200 includes coating a quantum dot solution on a first layer 202 and disposing a second layer 204 on the quantum dot layer 206. However, other process may be used. In the example, at least one of the first layer and second layer is a protective layer 400. The protective layer 400 can be applied by means of roll coating, gravure coating, knife coating, dip coating, curtain flow coating, spray coating, bar coating, die coating, spin coating or inkjet coating, by using a dispenser, or other means.

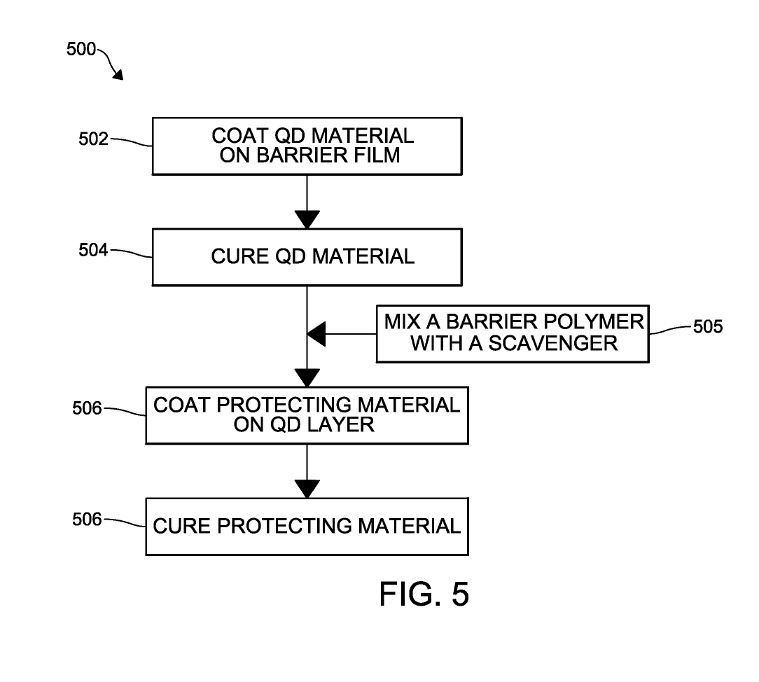

FIG. 5 shows a method according to aspects of the present disclosure. The method may comprise disposing a quantum dot solution on a barrier layer, at step 502. The quantum dot solution may be disposed on the barrier layer using a solution coating process.

At step 504, the quantum dot solution may be cured to form a quantum dot layer adhered to the barrier layer. The barrier layer may comprise a polysilazane-based polymer, a polysiloxane-based polymer, or a combination thereof.

At step 505, a protective solution is formed by mixing a barrier polymer with a scavenger as discussed above. At step 506, protective solution is disposed on the quantum dot layer. The protective solution may be disposed on the quantum dot layer using one or more of roll coating, gravure coating, knife coating, dip coating, curtain flow coating, spray coating, bar coating, die coating, spin coating or inkjet coating, by using a dispenser, or a combination thereof.

At step 508, the protective solution may be cured to form a protective layer adhered to the quantum dot layer. The protective solution may be cured using one or more of a radiation curing process including but not limited to a ultraviolet (UV) curing process, and a thermal curing process including but not limited to a steam curing process. The protective layer inhibits the permeation of at least oxygen and moisture into the quantum dot layer. The protective layer may optionally include a functional layer disposed adjacent an inorganic layer. The inorganic layer of the protective layer may include a polysilazane-based polymer, a polysiloxane-based polymer, or a combination thereof. As a further option, the protective layer may comprise, consists essentially of, or consist of a functional layer disposed adjacent a hybrid layer. The hybrid layer of the protective layer may comprises an organic component and an inorganic component. The inorganic component may comprise at least polysilazane-based polymer, a polysiloxane-based polymer, or a combination thereof.

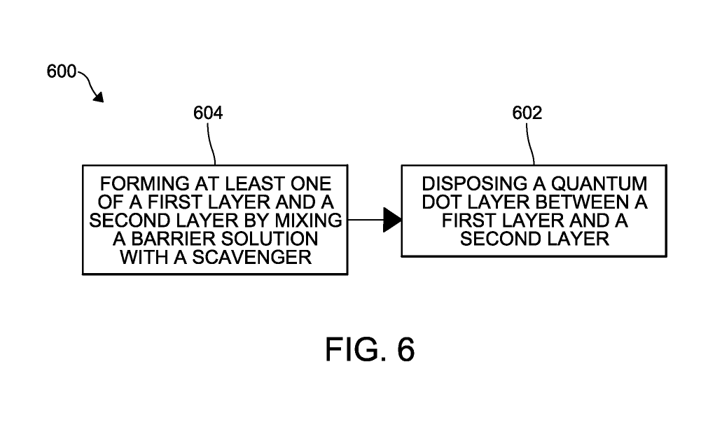

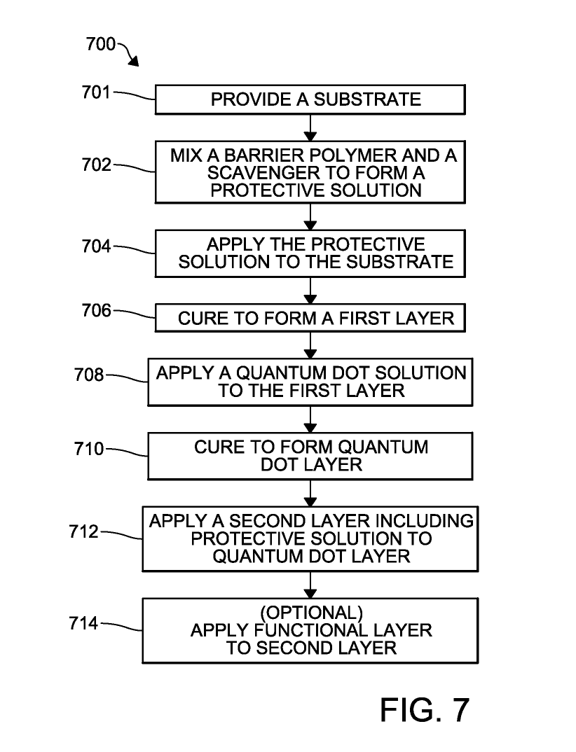

With reference to FIG. 6, a method 600 may comprise disposing a quantum dot layer between a first layer and a second layer at 602, mixing a barrier polymer and a scavenger at 604 to form at least one of the first layer and the second layer. The example shown in FIG. 5 encompasses forming a second layer with a protective solution including a barrier polymer and a scavenger. It will be understood that the construction of a film 200 where the first layer only is a protective layer may be formed according to the same method with the film inverted. FIG. 7 depicts an example where both the first layer (eg., 202, FIG. 2) and second layer (e.g., 204, FIG. 2) are formed from a protective solution including a barrier polymer and a scavenger as described above. In this example, the method 700 comprises providing a substrate at 701, mixing a barrier polymer and a scavenger to form a protective solution at 702; applying the protective solution to a substrate at 704. If needed to form first layer, the protective solution and substrate may be cured at step 706. A quantum dot solution is applied at step 708. If needed, the quantum dot solution is cured to form a quantum dot layer on top of first layer at 710. A second layer including the protective solution applied on quantum dot layer at step 712. The second layer is applied opposite first layer to cause quantum dot layer to be disposed between the first and second layers. At step 714, an optional functional layer may be applied to second layer. As discussed above functional layer may be selected to achieve desired surface characteristics or finishes, and may include a diffuser.

Once cured, the protective layer(s) may have a thickness that is less than the thickness of the barrier layer. As an example, the barrier layer may have a thickness of 100 microns and the protective layer may have a thickness of less than 100 microns. In another example, the protective layer 400 may have a thickness of less than 50 microns. Since the protective layer may have a thickness that is less than the barrier layer, the overall thickness of the stack of layers may be minimized compared to a stack having two of the barrier layers.

In accordance with the disclosures, providing a protective layer comprised of a barrier polymer with a scavenger provides higher intensity levels for light emitted from the quantum dot layer in the film 200 over time. In particular, intensity levels in films including a protective layer comprised of a barrier polymer and scavenger as described herein degrade at a rate lower than the rate for conventional quantum dot layers. The following experiment demonstrates a comparison of films having a protective layer created with solutions according to the disclosure having a scavenger to a solution without a scavenger (control). These solutions were then compared to a conventional quantum dot film.

Through simulation, films prepared according to the disclosure were compared to a conventional quantum dot layer to test a protective layer including a barrier polymer mixed with a scavenger according to the examples above. Protective solutions were prepared for comparison against the conventional quantum dot layer and a protective layer consisting of a barrier polymer without scavenger present. Table 1 presents the formulation for five prepared solutions. A first solution (Solution 1) included a barrier polymer (polysilazane-based polymer) in solvent (butyl ether) was created with 10% barrier polymer in 90% solvent and applied to a quantum dot layer. Additional solutions added a scavenger, where the amount of solvent was reduced in proportion to the addition of the scavenger. Solution 2 included 0.01% scavenger. Solution 3 included 0.1% scavenger. Solution 4 included 0.3% scavenger. Solution 5 included 0.5% scavenger.

TABLE 1
Components of prepared solutions.

| | | | | | | |
|---|---|---|---|---|---|---|
| Scaven- | Protocate- | — | 0.01% | 0.1% | 0.3% | 0.5% |
| ger | chuic acid | | | | | |
| Barrier | Polysilazane- | 10% | 10% | 10% | 10% | 10% |
| polymer | based | | | | | |
| | polymer | | | | | |
| Solvent | Butyl ether | 90% | 89.99% | 89.9% | 89.7% | 89.5% |

| | | | | | |
|---|---|---|---|---|---|
| Total | 100% | 100% | 100% | 100% | 100% |

In the experiment, protocatechuic acid (3,4-dihydroxybenzoic acid) was used as the scavenger. FIG. 8 compares the measured intensity of the quantum dot layer in a conventional quantum dot film with solution 1 with the barrier polymer and solvent, and a solution having barrier polymer and scavenger according to the disclosure. It was observed that the conventional QD film intensity level decreased more rapidly than the solution 1 and the protective layer solution including a scavenger. FIG. 8 shows a slower rate of decreasing intensity for both solutions compared to the conventional film. The presence of the scavenger demonstrated a much lower rate of decrease at the outset maintaining a relatively high level of intensity in comparison to the sharp drop off in intensity exhibited by the conventional QD film and the non-scavenger control solution. Both of these solutions dropped from an initial intensity of 1 (l/lo) to 0.8 or less in the first 50 hours. For the control solution, film stabilized after the initial drop off exhibiting a decreasing intensity rate similar to the rate demonstrated by the barrier polymer with the scavenger present. The conventional QD film, however, continued to decrease at a high rate until the intensity reached zero at about 300 hours. Improved intensity stability was observed in the protective layer solution including the scavenger. As noted, the initial rate of decrease in intensity was markedly lower. The observed rate was approximately 0.00004 PL per hour in the first 50 hours compared to a rate of intensity loss in the control solution of about 0.004 PL and similar rate of intensity loss in the conventional QD film. Following the initial 50 hour period, the rate of decrease in intensity for the barrier polymer with scavenger fell within a range of about 0.00004 PL per hour and 0.0007 per hour.

### Aspects

The present disclosure comprises at least the following aspects.

Aspect 1A. An article comprising a first layer and a second layer; a quantum dot layer disposed between the first layer and the second layer; and wherein at least one of the first layer and the second layer is a protective layer, the protective layer comprising a barrier polymer and a scavenger, wherein the protective layer inhibits the permeation of at least oxygen and moisture into the quantum dot layer.

Aspect 1B. An article consisting essentially of: a first layer and a second layer; a quantum dot layer disposed between the first layer and the second layer; and wherein at least one of the first layer and the second layer is a protective layer, the protective layer comprising a barrier polymer and a scavenger, wherein the protective layer inhibits the permeation of at least oxygen and moisture into the quantum dot layer.

Aspect 1C. An article consisting of: a first layer and a second layer; a quantum dot layer disposed between the first layer and the second layer; and wherein at least one of the first layer and the second layer is a protective layer, the protective layer comprising a barrier polymer and a scavenger, wherein the protective layer inhibits the permeation of at least oxygen and moisture into the quantum dot layer.

Aspect 2. The film of example 1, wherein the scavenger is a phenolic acid.

Aspect 3. The film of any one examples 1-2, wherein the scavenger is a protocatechuic acid.

Aspect 4. The film of any one examples 1-3, wherein the first layer is a barrier layer and wherein the quantum dot layer is disposed on the barrier layer using a solution coating process.

Aspect 5. The film of examples 1-3, wherein the first layer is a protective layer and the second layer is a protective layer, wherein the first layer a substrate underlying the barrier polymer and the scavenger.

Aspect 6. The film of any one of examples 1-5, wherein the protective layer comprises the inorganic layer and the inorganic layer comprises a polysilazane-based polymer, a polysiloxane-based polymer, or a combination thereof.

Aspect 7. The film of any one of examples 1-6, wherein the protective layer comprises the hybrid layer and the hybrid layer comprises an organic component and inorganic component.

Aspect 8. The film of any one of examples 1-7, further comprising a functional layer provided outward of the protective layer.

Aspect 9. The film of any one of examples 1-8, wherein the functional layer is a diffuser.

Aspect 10. The film of example 9, wherein the functional layer is a prism.

Aspect 11. The film of any one of examples 1-9, wherein the second layer is disposed on the quantum dot layer using a solution coating process.

Aspect 12. The film of any one of claims 1-11, wherein the scavenger is present in an amount less than 0.5%.

Aspect 13. The film of any one of claims 1-12, wherein the scavenger is present in a range of about 0.01% to about 0.5%.

Aspect 14. The film of any one of claims 1-13, wherein the protecting layer has a thickness in the range of about 50 nanometers to about 50 micrometers.

Aspect 15. A light emitting device comprising the film of any one of examples 1-14.

Aspect 16A. A film for light emitting devices, the film formed from a process comprising disposing a quantum dot solution between a first layer and a second layer to form a quantum dot layer, where at least one of the first layer and second layer is a protective layer; and wherein the protective layer is formed by mixing a barrier polymer with a scavenger.

Aspect 16B. A film for light emitting devices, the film formed from a process consisting essentially of disposing a quantum dot solution between a first layer and a second layer to form a quantum dot layer, where at least one of the first layer and second layer is a protective layer; and wherein the protective layer is formed by mixing a barrier polymer with a scavenger.

Aspect 16C. A film for light emitting devices, the film formed from a process consisting of: disposing a quantum dot solution between a first layer and a second layer to form a quantum dot layer, where at least one of the first layer and second layer is a protective layer; and wherein the protective layer is formed by mixing a barrier polymer with a scavenger.

Aspect 17. The film of example 16A, further comprising a functional layer disposed adjacent to the second layer.

Aspect 18. The film of example 16A, wherein the barrier polymer comprises a polysilazane-based polymer, a polysiloxane-based polymer, or a combination thereof.

Aspect 19. The film of example 16A, wherein the protective layer further comprises a functional layer.

Aspect 20. The film of example 19, wherein the functional layer is a diffuser.

Aspect 21. The film of claim 19, wherein the functional layer is a prism.

Aspect 22. The film of any one examples 16A-21, wherein the first layer is a barrier layer.

Aspect 23. The film of any one examples 16A-22, wherein the quantum dot solution is disposed on the barrier layer using a solution coating process.

Aspect 24. The film of any one examples 16A-23, wherein the protective layer is the second layer, and wherein the second layer is disposed on the quantum dot layer using a solution coating process.

Aspect 25. The film of any one examples 16A-24, wherein at least one of the layers is cured using one or more of a radiation curing process and a thermal curing process.

Aspect 26. The film of any one examples 24-25, wherein the solution coating process includes at least one of roll coating, gravure coating, knife coating, dip coating, curtain flow coating, spray coating, bar coating, die coating, spin coating or inkjet coating, by using a dispenser, or a combination thereof.

Aspect 27. A light emitting device comprising the film of any one of examples 16-26.

Aspect 28A. A method comprising: disposing a quantum dot solution on a first layer to form a quantum dot layer; applying a second layer to the quantum dot solution; wherein at least one of the first layer and second layer are a protective layer formed by providing a barrier polymer with a scavenger, wherein the scavenger absorbs at least one of oxygen and water to inhibit the at least one of oxygen and water from reacting with the quantum dot solution; and curing the first layer, second layer and quantum dot solution to form a film comprising a stack of the first layer, the quantum dot layer, and the second layer.

Aspect 28B. A method consisting essentially of: disposing a quantum dot solution on a first layer to form a quantum dot layer; applying a second layer to the quantum dot solution; wherein at least one of the first layer and second layer are a protective layer formed by providing a barrier polymer with a scavenger, wherein the scavenger absorbs at least one of oxygen and water to inhibit the at least one of oxygen and water from reacting with the quantum dot solution; and curing the first layer, second layer and quantum dot solution to form a film comprising a stack of the first layer, the quantum dot layer, and the second layer.

Aspect 28C. A method consisting of: disposing a quantum dot solution on a first layer to form a quantum dot layer; applying a second layer to the quantum dot solution; wherein at least one of the first layer and second layer are a protective layer formed by providing a barrier polymer with a scavenger, wherein the scavenger absorbs at least one of oxygen and water to inhibit the at least one of oxygen and water from reacting with the quantum dot solution; and curing the first layer, second layer and quantum dot solution to form a film comprising a stack of the first layer, the quantum dot layer, and the second layer.

### Definitions

It is to be understood that the terminology used herein is for the purpose of describing particular aspects only and is not intended to be limiting. As used in the specification and in the claims, the term “comprising” can include the aspects “consisting of” and “consisting essentially of.” Unless defined otherwise, all technical and scientific terms used herein have the same meaning as commonly understood by one of ordinary skill in the art to which this disclosure belongs. In this specification and in the claims which follow, reference will be made to a number of terms which shall be defined herein.

Ranges can be expressed herein as from one value (first value) to another value (second value). When such a range is expressed, the range includes in some aspects one or both of the first value and the second value. Throughout this document, values expressed in a range format thus may be interpreted in a flexible manner to include not only the numerical values explicitly recited as the limits of the range, but also to include all the individual numerical values or sub-ranges encompassed within that range as if each numerical value and sub-range is explicitly recited. As used herein, the terms “about” and “at or about” mean that the amount or value in question can be the designated value, approximately the designated value, or about the same as the designated value. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges (e.g., 0.1% to 0.5%, 1.1% to 2.2%, 3.3% to 4.4%) within the indicated range. The statement “about X to Y” has the same meaning as “about X to about Y,” unless indicated otherwise. Likewise, the statement “about X, Y, or about Z” has the same meaning as “about X, about Y, or about Z,” unless indicated otherwise. The term “about” as used herein can allow for a degree of variability in a value or range, for example, within 10%, within 5%, or within 1% of a stated value or of a stated limit of a range, and includes the exact stated value or range. The term “substantially” as used herein refers to a majority of, or mostly, as in at least about 50%, 60%, 70%, 80%, 90%, 95%, 96%, 97%, 98%, 99%, 99.5%, 99.9%, 99.99%, or at least about 99.999% or more, or 100%.

In this document, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, it is to be understood that the phraseology or terminology employed herein, and not otherwise defined, is for the purpose of description only and not of limitation. Any use of section headings is intended to aid reading of the document and is not to be interpreted as limiting; information that is relevant to a section heading may occur within or outside of that particular section.

In the methods described herein, the acts can be carried out in any order without departing from the principles of the invention, except when a temporal or operational sequence is explicitly recited. Furthermore, specified acts can be carried out concurrently unless explicit claim language recites that they be carried out separately. For example, a claimed act of doing X and a claimed act of doing Y can be conducted simultaneously within a single operation, and the resulting process will fall within the literal scope of the claimed process.

The term “organic group” as used herein refers to any carbon-containing functional group. For example, an oxygen-containing group such as an alkoxy group, aryloxy group, aralkyloxy group, oxo(carbonyl) group, a carboxyl group including a carboxylic acid, carboxylate, and a carboxylate ester; a sulfur-containing group such as an alkyl and aryl sulfide group; and other heteroatom-containing groups. Non-limiting examples of organic groups include OR, OOR, OC(O)N(R)₂, CN, CF₃, OCF₃, R, C(O), methylenedioxy, ethylenedioxy, N(R)₂, SR, SOR, SO₂R, SO₂N(R)₂, SO₃R, C(O)R, C(O)C(O)R, C(O)CH₂C(O)R, C(S)R, C(O)OR, OC(O)R, C(O)N(R)₂, OC(O)N(R)₂, C(S)N(R)₂, (CH₂)₀₋₂N(R)C(O)R, (CH₂)₀₋₂N(R)N(R)₂, N(R)N(R)C(O)R, N(R)N(R)C(O)OR, N(R)N(R)CON(R)₂, N(R)SO₂R, N(R)SO₂N(R)₂, N(R)C(O)OR, N(R)C(O)R, N(R)C(S)R, N(R)C(O)N(R)₂, N(R)C(S)N(R)₂, N(COR)COR, N(OR)R, C(═NH)N(R)₂, C(O)N(OR)R, C(═NOR)R, and substituted or unsubstituted (C₁-C₁₀₀)hydrocarbyl, wherein R can be hydrogen (in examples that include other carbon atoms) or a carbon-based moiety, and wherein the carbon-based moiety can be substituted or unsubstituted.

The term “substituted” as used herein in conjunction with a molecule or an organic group as defined herein refers to the state in which one or more hydrogen atoms contained therein are replaced by one or more non-hydrogen atoms. The term “functional group” or “substituent” as used herein refers to a group that can be or is substituted onto a molecule or onto an organic group. Examples of substituents or functional groups include, but are not limited to, a halogen (e.g., fluorine F, chlorine C₁, bromine Br, and iodine I); an oxygen atom in groups such as hydroxy groups, alkoxy groups, aryloxy groups, aralkyloxy groups, oxo(carbonyl) groups, carboxyl groups including carboxylic acids, carboxylates, and carboxylate esters; a sulfur atom in groups such as thiol groups, alkyl and aryl sulfide groups, sulfoxide groups, sulfone groups, sulfonyl groups, and sulfonamide groups; a nitrogen atom in groups such as amines, hydroxyamines, nitriles, nitro groups, N-oxides, hydrazides, azides, and enamines; and other heteroatoms in various other groups. Non-limiting examples of substituents that can be bonded to a substituted carbon (or other) atom include F, Cl, Br, I, OR, OC(O)N(R)₂, CN, NO, NO₂, ONO₂, azido, CF₃, OCF₃, R, O (oxo), S (thiono), C(O), S(O), methylenedioxy, ethylenedioxy, N(R)₂, SR, SOR, SO₂R, SO₂N(R)₂, SO₃R, C(O)R, C(O)C(O)R, C(O)CH₂C(O)R, C(S)R, C(O)OR, OC(O)R, C(O)N(R)₂, OC(O)N(R)₂, C(S)N(R)₂, (CH₂)₀₋₂N(R)C(O)R, (CH₂)₀₋₂N(R)N(R)₂, N(R)N(R)C(O)R, N(R)N(R)C(O)OR, N(R)N(R)CON(R)₂, N(R)SO₂R, N(R)SO₂N(R)₂, N(R)C(O)OR, N(R)C(O)R, N(R)C(S)R, N(R)C(O)N(R)₂, N(R)C(S)N(R)₂, N(COR)COR, N(OR)R, C(═NH)N(R)₂, C(O)N(OR)R, and C(═NOR)R, wherein R can be hydrogen or a carbon-based moiety; for example, R can be hydrogen, (C₁-C₁₀₀)hydrocarbyl, alkyl, acyl, cycloalkyl, aryl, aralkyl, heterocyclyl, heteroaryl, or heteroarylalkyl; or wherein two R groups bonded to a nitrogen atom or to adjacent nitrogen atoms can together with the nitrogen atom or atoms form a heterocyclyl.

The term “alkyl” as used herein refers to straight chain and branched alkyl groups and cycloalkyl groups. Examples of straight chain alkyl groups include those with from 1 to 8 carbon atoms such as methyl, ethyl, n-propyl, n-butyl, n-pentyl, n-hexyl, n-heptyl, and n-octyl groups. Examples of branched alkyl groups include, but are not limited to, isopropyl, iso-butyl, sec-butyl, t-butyl, neopentyl, isopentyl, and 2,2-dimethylpropyl groups.

The term “alkenyl” as used herein refers to straight and branched chain and cyclic alkyl groups as defined herein, except that at least one double bond exists between two carbon atoms.

The term “acyl” as used herein refers to a group containing a carbonyl moiety wherein the group is bonded via the carbonyl carbon atom.

The term “cycloalkyl” as used herein refers to cyclic alkyl groups such as, but not limited to, cyclopropyl, cyclobutyl, cyclopentyl, cyclohexyl, cycloheptyl, and cyclooctyl groups. In some aspects, the cycloalkyl group can have 3 to about 8-12 ring members, whereas in other aspects the number of ring carbon atoms range from 3 to 4, 5, 6, or 7

The term “aryl” as used herein refers to cyclic aromatic hydrocarbon groups that do not contain heteroatoms in the ring. Thus aryl groups include, but are not limited to, phenyl, azulenyl, heptalenyl, biphenyl, indacenyl, fluorenyl, phenanthrenyl, triphenylenyl, pyrenyl, naphthacenyl, chrysenyl, biphenylenyl, anthracenyl, and naphthyl groups.

The term “heterocyclyl” as used herein refers to aromatic and non-aromatic ring compounds containing three or more ring members, of which one or more is a heteroatom such as, but not limited to, nitrogen N, oxygen O, and sulfur S.

The term “alkoxy” as used herein refers to an oxygen atom connected to an alkyl group, including a cycloalkyl group, as are defined herein.

The terms “halo,” “halogen,” or “halide” group, as used herein, by themselves or as part of another substituent, mean, unless otherwise stated, a fluorine, chlorine, bromine, or iodine atom.

The term “haloalkyl” group, as used herein, includes mono-halo alkyl groups, poly-halo alkyl groups wherein all halo atoms can be the same or different, and per-halo alkyl groups, wherein all hydrogen atoms are replaced by halogen atoms, such as fluoro. Examples of haloalkyl include trifluoromethyl, 1,1-dichloroethyl, 1,2-dichloroethyl, 1,3-dibromo-3,3-difluoropropyl, perfluorobutyl, and the like.

The term “hydrocarbon” or “hydrocarbyl” as used herein refers to a molecule or functional group, respectively, that includes carbon and hydrogen atoms. The term can also refer to a molecule or functional group that normally includes both carbon and hydrogen atoms but wherein all the hydrogen atoms are substituted with other functional groups.

As used herein, the term “hydrocarbyl” refers to a functional group derived from a straight chain, branched, or cyclic hydrocarbon, and can be alkyl, alkenyl, alkynyl, aryl, cycloalkyl, acyl, or any combination thereof. Hydrocarbyl groups can be shown as (Cₐ-C_{b})hydrocarbyl, wherein a and b are integers and mean having any of a to b number of carbon atoms. For example, (C₁-C₄)hydrocarbyl means the hydrocarbyl group can be methyl (C₁), ethyl (C₂), propyl (C₃), or butyl (C₄), and (C₀-C_{b})hydrocarbyl means in certain aspects there is no hydrocarbyl group.

The term “number-average molecular weight” (Mₙ) as used herein refers to the ordinary arithmetic mean of the molecular weight of individual molecules in a sample. It is defined as the total weight of all molecules in a sample divided by the total number of molecules in the sample. Experimentally, Mₙ is determined by analyzing a sample divided into molecular weight fractions of species i having nᵢ molecules of molecular weight Mᵢ through the formula Mₙ=ΣMᵢnᵢ/Σnᵢ. The Mₙ can be measured by a variety of well-known methods including gel permeation chromatography, spectroscopic end group analysis, and osmometry. If unspecified, molecular weights of polymers given herein are number-average molecular weights.

The term “weight-average molecular weight” as used herein refers to M_{w}, which is equal to ΣMᵢ²nᵢ/ΣMᵢnᵢ, where nᵢ is the number of molecules of molecular weight Mᵢ. In various examples, the weight-average molecular weight can be determined using light scattering, small angle neutron scattering, X-ray scattering, and sedimentation velocity.

The term “radiation” as used herein refers to energetic particles travelling through a medium or space. Examples of radiation are visible light, infrared light, microwaves, radio waves, very low frequency waves, extremely low frequency waves, thermal radiation (heat), and black-body radiation.

The term “UV light” as used herein refers to ultraviolet light, which is electromagnetic radiation with a wavelength of about 10 nm to about 400 nm.

The term “cure” as used herein refers to exposing to radiation in any form, heating, or allowing to undergo a physical or chemical reaction that results in hardening or an increase in viscosity.

The term “solvent” as used herein refers to a liquid that can dissolve a solid, liquid, or gas. Non-limiting examples of solvents are silicones, organic compounds, water, alcohols, ionic liquids, and supercritical fluids.

The term “coating” as used herein refers to a continuous or discontinuous layer of material on the coated surface, wherein the layer of material can penetrate the surface and can fill areas such as pores, wherein the layer of material can have any three-dimensional shape, including a flat or curved plane. In one example, a coating can be formed on one or more surfaces, any of which may be porous or nonporous, by immersion in a bath of coating material.

The term “surface” as used herein refers to a boundary or side of an object, wherein the boundary or side can have any perimeter shape and can have any three-dimensional shape, including flat, curved, or angular, wherein the boundary or side can be continuous or discontinuous. While the term surface generally refers to the outermost boundary of an object with no implied depth, when the term ‘pores’ is used in reference to a surface, it refers to both the surface opening and the depth to which the pores extend beneath the surface into the substrate.

As used herein, the term “polymer” refers to a molecule having at least one repeating unit and can include copolymers.

The polymers described herein can terminate in any suitable way. In some aspects, the polymers can terminate with an end group that is independently chosen from a suitable polymerization initiator, —H, —OH, a substituted or unsubstituted (C₁-C₂₀)hydrocarbyl (e.g., (C₁-C₁₀)alkyl or (C₆-C₂₀)aryl) interrupted with 0, 1, 2, or 3 groups independently selected from —O—, substituted or unsubstituted —NH—, and —S—, a poly(substituted or unsubstituted (C₁-C₂₀)hydrocarbyloxy), and a poly(substituted or unsubstituted (C₁-C₂₀)hydrocarbylamino).

Illustrative types of polyethylene include, for example, ultra-high molecular weight polyethylene (UHMWPE, for example, a molar mass between 3.5 and 7.5 million atomic mass units), ultra-low molecular weight polyethylene (ULMWPE), high molecular weight polyethylene (HMWPE), high density polyethylene (HDPE, for example, a density of about 0.93 to 0.97 grams per cubic centimeter (g/cm³) or 970 kilograms per cubic meter (kg/m³)), high density cross-linked polyethylene (HDXLPE, for example, a density of about 0.938 to about 0.946 g/cm³), cross-linked polyethylene (PEX or XLPE, for example, a degree of cross-linking of between 65 and 89% according to ASTM F876), medium density polyethylene (MDPE, for example, a density of 0.926 to 0.940 g/cm³), low density polyethylene (LDPE, for example, about 0.910 g/cm³ to 0.940 g/cm³), linear low density polyethylene (LLDPE) and very low density polyethylene (VLDPE, for example, a density of about 0.880 to 0.915 g/cm³).

It will be apparent to those skilled in the art that various modifications and variations can be made in the present disclosure without departing from the scope or spirit of the disclosure. Other aspects of the disclosure will be apparent to those skilled in the art from consideration of the specification and practice of the disclosure disclosed herein. It is intended that the specification and examples be considered as exemplary only, with a true scope and spirit of the disclosure being indicated by the following claims.

The patentable scope of the disclosure is defined by the claims, and can include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A light emitting film comprising:
a first layer and a second layer;
a quantum dot layer disposed between the first layer and the second layer; and
wherein at least one of the first layer and the second layer is a protective layer, the protective layer comprising a barrier polymer and a scavenger, wherein the protective layer inhibits permeation of at least oxygen and moisture into the quantum dot layer.

2. The film of claim 1, wherein the scavenger is a phenolic acid.

3. The film of claim 1, wherein the scavenger is selected from the group consisting of galic acid, p-coumaric acid, caffeic acid, rosemaric acid and protocatechuic acid.

4. The film of claim 1, wherein the first layer is a barrier layer and wherein the quantum dot layer is disposed on the barrier layer using a solution coating process.

5. The film of claim 1, wherein the first layer is a protective layer and the second layer is a protective layer, wherein the first layer a substrate underlying the barrier polymer and the scavenger.

6. The film of claim 1, wherein the protective layer comprises an inorganic layer and the inorganic layer comprises a polysilazane-based polymer, a polysiloxane-based polymer, or a combination thereof.

7. The film of claim 1, wherein the protective layer comprises a hybrid layer and the hybrid layer comprises an organic component and inorganic component.

8. The film of claim 1, further comprising a functional layer provided outward of the protective layer.

9. The film of claim 1, wherein the functional layer is a diffuser.

10. The film of claim 1, wherein the functional layer is a prism.

11. The film of claim 1, wherein the second layer is disposed on the quantum dot layer using a solution coating process.

12. The film of claim 1, wherein the scavenger is present in an amount less than 0.5 wt. %.

13. The film of claim 1, wherein the scavenger is present in an amount from about 0.01% to about 0.5%.

14. The film of claim 1, wherein the protecting layer has a thickness in the range of about 50 nanometers to about 50 micrometers.

15. A light emitting device comprising the film of claim 1.

16. A film for light emitting devices, the film formed from a process comprising:
disposing a quantum dot solution between a first layer and a second layer to form a quantum dot layer, where at least one of the first layer and second layer is a protective layer; and
wherein the protective layer is formed by mixing a barrier polymer with a scavenger.

17. The film of claim 16, wherein the barrier polymer comprises a polysilazane-based polymer, a polysiloxane-based polymer, or a combination thereof.

18. The film of claim 16, wherein the protective layer further comprises a functional layer.

19. A light emitting device comprising the film of claim 16.

20. A method comprising:
disposing a quantum dot solution on a first layer; applying a second layer to the quantum dot solution; wherein at least one of the first layer and second layer are a protective layer formed by providing a barrier polymer with a scavenger, wherein the scavenger absorbs at least one of oxygen and water to inhibit the at least one of oxygen and water from reacting with the quantum dot solution; and
curing the first layer, second layer and quantum dot solution to form a film comprising a stack of the first layer, the quantum dot layer, and the second layer.
